(19) United States
(12) Patent Application Publication
(10) Pub. No.: US 2011/0013466 A1
(43) Pub. Date: Jan. 20, 2011

(54) SEMICONDUCTOR APPARATUS AND DATA READING METHOD

(75) Inventor: Tatsuya ISHIZAKI, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/823,702

(22) Filed: Jun. 25, 2010

(30) Foreign Application Priority Data
Jul. 17, 2009 (JP) 2009-168848

(51) Int. Cl. G11C 7/00

(52) U.S. Cl. 365/189.15

(57) ABSTRACT

A semiconductor device includes multiple memory cells, a first and second digit lines, where either of them is coupled to the memory cell to be read, a sense amplifier having a first and second sense nodes that are respectively connected to the first and second digit lines, a first switch between the first digit line and the first sense node, a second switch between the second digit line and the second sense node, and a control circuit that outputs a first and second control signals for controlling a conducive state of the first and second switches. When an activation of the sense amplifier is started, the control circuit makes the first and second switches conductive and disconnects the first or second switch corresponding to the digit line to which the memory cell to be read is not connected according to a potential difference between the first and second sense nodes.

### INCORPORATION BY REFERENCE

This application is based upon and claims the benefit of priority from Japanese patent application No. 2009-168848, filed on Jul. 17, 2009, the disclosure of which is incorporated herein in its entirety by reference.

### BACKGROUND

1. Field of the Invention

The present invention relates to a semiconductor device and a method of reading data.

2. Description of Related Art

In recent years, network terminals, such as a router, are becoming widely available in the market along with the spread of the Internet. Usually SRAM (Static Random Access Memory) is used for the memory in the router. One of the reasons that SRAM is used as the network terminal such as a router is that it takes little time until the first data is read at the time of requesting the memory to output data.

However, there is a problem in SRAM that the chip size for storing the data with the same capacity is larger than DRAM (Dynamic Random Access Memory) which can store data in one capacitor.

Therefore, it is ideal to realize DRAM that requires about the same time as SRAM until the first data is read. Then it is possible to improve the read speed and also mount DRAM with smaller chip size in the router, thereby contributing to miniaturize the router.

FIG. 4 illustrates the configuration of a semiconductor device disclosed in Japanese Unexamined Patent Application Publication No. 2000-149551. This semiconductor device includes digit lines D0 and #D0, and a sense amplifier 40. The two digit lines D0 and #D0 have the same length and are connected to the sense amplifier 40. The sense amplifier amplifies a potential difference between the digit line pair.

Further above the drawing, there is the cell array (not illustrated) including cells arranged symmetrically to the memory cells C0 to C3 with respect to the sense amplifier 40. The cell array not illustrated and the illustrated cell array share one sense amplifier 40. Switches SW0 and #SW0 are provided between the illustrated cell array and the sense amplifier 40. Similarly, switches DSW0 and #DSW0 (not illustrated) are provided between the cell array not illustrated and the sense amplifier 40. By turning on and off the switches DSW0 and #DSW0 which are provided between the sense amplifier and each of the cell arrays, it is possible to switch the cell array to connect the sense amplifier 40.

The switches DSW0 and #DSW0 interposed between the illustrated cell array and the sense amplifier 40 are controlled to turn on and off by a control signal CUTD0. Similarly, the switches DSW0 and #DSW0 (not illustrated) interposed between the cell array (not illustrated) and the sense amplifier 40 are commonly turned on and off by the control signal CUTD0 (not illustrated).

In order to connect the illustrated cell array and the sense amplifier 40, the switches DSW0 and #DSW0 interposed between the sense amplifier 40 and the illustrated cell array are turned on at the same time, and the switches DSW0 and #DSW0 between the sense amplifier 40 and the memory cells not illustrated are turned off at the same time. In a similar manner, in order to connect the sense amplifier 40 and the cell array not illustrated, the switches DSW0 and #DSW0 interposed between the sense amplifier 40 and the illustrated cell array are turned off at the same time, and the switches DSW0 and #DSW0 interposed between the sense amplifier 40 and the memory cells not illustrated are turned on at the same time. The operation of the semiconductor device of the related art in a case of reading data from the illustrated cell array is described hereinafter.

While the sense amplifier 40 is amplifying the digit line pair, the control signal CUTD0 is activated, and the switches DSW0 and #DSW0, which are connected between the illustrated memory cells and the sense amplifier 40, are turned on. In this state, by selecting desired word lines WL0 to WL3 to which the memory cells C0 to C3 to be read are connected, a potential difference is generated between the digit line (for example, #D0), which is connected to the cell corresponding to the selected word line, and the digit line (for example, #D0), which is not connected to the memory cell corresponding to the selected word line. The sense amplifier 40 operates reading the date stored in the memory cells C0 to C3 by amplifies the potential difference.

Further, Japanese Unexamined Patent Application Publication No. 2001-273771 discloses the refresh method in DRAM. The technique disclosed in Japanese Unexamined Patent Application Publication No. 2001-273771 reads data from one pair of digit lines, to which a memory cell to be refreshed is coupled, into a sense node, disconnects the pair of digit lines from the sense node, and then amplifies a potential difference generated in the sense node by a sense amplifier. After the potential difference is amplified by the sense amplifier, only the digit lines to which the memory cells are coupled are selected to re-record the selected data.

### SUMMARY

However, in DRAM that has the circuit configuration (see FIG. 4) disclosed in Japanese Unexamined Patent Application Publication No. 2000-149551, when the sense amplifier 40 amplifies the potential difference of the digit line pair, the sense amplifier 40 needs to drive two digit lines with the same length over the entire amplification period.

Generally, a digit line pair is formed from one end of a memory sub-array to the other end of the memory sub-array. Therefore, in the semiconductor device disclosed in Japanese Unexamined Patent Application Publication No. 2000-149551, when amplifying the digit line (with large wiring resistance and capacitance) connected to the cell corresponding to the selected word line, the load is imposed on the sense amplifier 40, and thereby increasing the amplification time. The present inventor has found a problem that this reduces the reading speed of data.

On the other hand, the method disclosed by Japanese Unexamined Patent Application Publication No. 2001-273771 is a method to refresh data in DRAM and does not mention anything about the method to read data. In Japanese Unexamined Patent Application Publication No. 2001-273771, both of the two digit lines which compose the digit line pair are disconnected from the sense node at the stage of amplifying the potential difference generated in the data which is read from one digit line into the sense node. After that, the digit line, to which the memory cell to be refreshed is connected, is connected to the sense node (see FIG. 4B in Japanese Unexamined Patent Application Publication No. 2001-273771). Therefore, the present inventor has found a problem that even when applying the refresh method disclosed in Japanese Unexamined Patent Application Publication No. 2001-273771 to the data reading method, the time required to read data increases due to the disconnect operation of the sense node and the digit line pair.

An exemplary aspect of the present invention is a semiconductor device that includes a plurality of memory cells, a first digit line and a second digit line, where one of the first digit line and the second digit line being coupled to the memory cell to be read among the plurality of memory cells, a sense amplifier including a first sense node and a second sense node that are respectively connected to the first digit line and the second digit line, a first switch that is interposed between the first digit line and the first sense node, a second switch that is interposed between the second digit line and the second sense node, and a control circuit that outputs a first control signal and a second control signal for controlling a conducive state of the first switch and the second switch. At the time of starting an activation of the sense amplifier, the control circuit makes the first switch and the second switch conductive, and disconnects one of the first switch and the second switch corresponding to the digit line to which the memory cell to be read is not connected according to a potential difference between the first sense node and the second sense node.

As described so far, by connecting the first and the second digit lines to the sense amplifier from when activation of the sense amplifier is started, and then disconnecting the digit lines not connected to the memory cell to be read from the sense amplifier according to the potential difference between the first and the second sense nodes, it is possible to reduce the load imposed on the sense amplifier which is in the amplification period of the potential difference between the first and the second digit lines. Further, this enables to reduce the amplification time of the potential difference.

The present invention provides a semiconductor device that achieves to increase the speed of reading data.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 illustrates a configuration example of a semiconductor device according to an exemplary embodiment;

FIG. 2 illustrates an operation example of the semiconductor device according to the exemplary embodiment;

FIG. 3 illustrates another operation example of the semiconductor device according to the exemplary embodiment; and

FIG. 4 illustrates the configuration of a semiconductor device according to a related art.

### DETAILED DESCRIPTION OF THE EXEMPLARY EMBODIMENTS

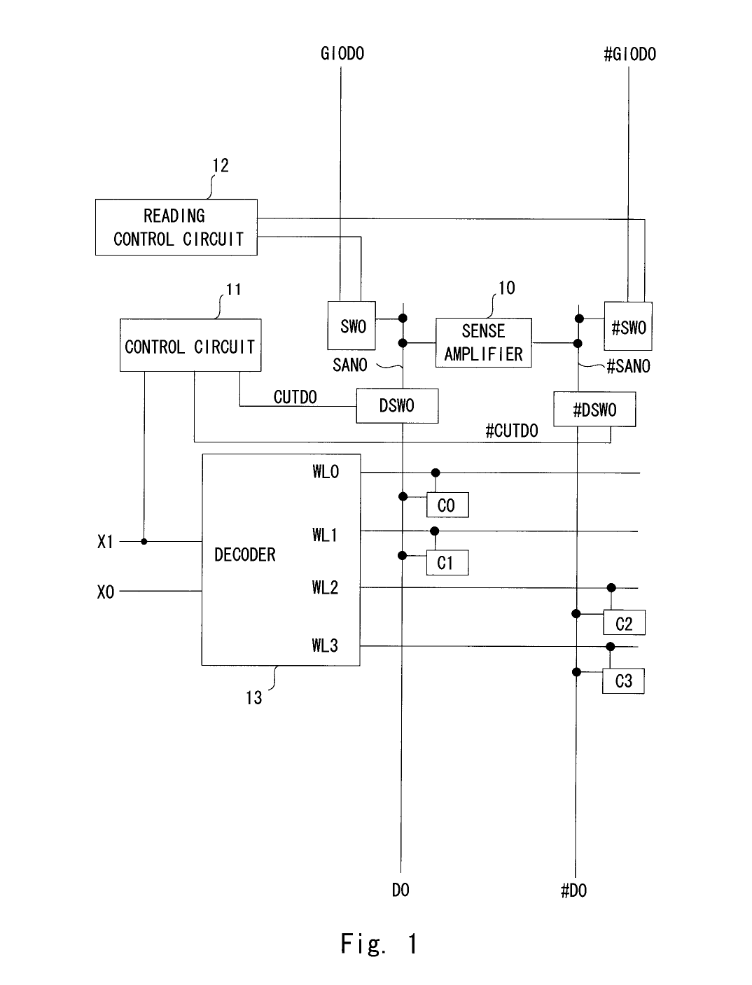

Hereinafter, an exemplary embodiment of the best mode of the present invention is described with reference to the drawings. FIG. 1 illustrates a configuration example of a semiconductor device according to an exemplary embodiment of the present invention. Note that FIG. 1 illustrates only a part of the semiconductor device in order to explain the semiconductor device according to this exemplary embodiment.

This semiconductor device includes multiple memory cells C0 to C3, a first digit line D0, and a second digit line #D0. One of the memory cells C0 to C3 to be read is coupled to either the first digit line D0 or the second digit line #D0. Further, the semiconductor device includes a sense amplifier 10 that has a first and second sense nodes, which are respectively coupled to the first and second digit lines D0 and #D0, a first switch DSW0 between the first digit line D0 and the first sense node SAN0, a second switch #DSW0 between the second digit line #D0 and the second sense node #SAN0, and a control circuit 11 which outputs a first control signal CUTD0 and a second control signal #DSW0 for controlling the conductive state of the first switch DSW0 and the second switch #DSW0.

The control circuit 11 makes the first switch DSW0 and the second switch #DSW0 conductive at the time when the activation of the sense amplifier 10 is started. After that, the control circuit 11 disconnects either the first switch DSW0 or the second switch #DSW0 corresponding to the digit line D0 or #D0 to which the memory cell to be read is not connected according to the potential difference between the first and second sense nodes SAN0 and #SAN0. In the following explanation, the digit line to which the memory cell to be read is connected is referred to as a reading digit line. Further, the digit line to be paired with the reading digit line and also not connected to a memory cell to be read is referred to as a non-reading digit line.

As described above, at the time of reading data, by disconnecting the non-reading digit line to which the memory cell to be read is not connected from the sense amplifier 10 according to the potential difference (potential difference between the digit lines) between the first sense node SAN and the second sense node #SAN0, it is possible to reduce the load imposed on the sense amplifier 10 at the time of amplifying the potential difference of the digit line pair (D0 and #D0).

Hereinafter, the configuration and the operation of the semiconductor device according to this exemplary embodiment are described in detail.

As illustrated in FIG. 1, each of the memory cells C0 to C3 is connected to either the first digit line D0 or the second digit line #D0. Each of the memory cells C0 to C3 includes a capacitor (not illustrated) for storing data as an electric charge and a switching transistor (not illustrated) for switching whether to connect the capacitor to the first digit line D0 or the second digit line #D0. The word lines WL0 to WL3 are connected to the gates of the switching transistors. Word line selection control signals X0 and X1 for selecting the word lines WL0 to WL3 to be activated switches the connection of the memory cells C0 to C3 to either the first digit line D0 or the second digit line #D0.

A decoder 13 selects the word lines W0 to WL3 to be activated according to the word line selection control signals X0 and X1 which are supplied externally. Specifically, the decoder 13 selects the word lines WL0 to WL3 corresponding to four ways of combinations for the bits specifying the word line selection signal X0 and the bits specifying the word line selection signal X1 among predetermined bits composing the word line address. Specifically, the word line selection signal X1 selects either the pair of the word lines WL0 and WL1 or the pair of the word lines WL2 and WL3. The word line selection signal X0 selects either of the word lines of the pair selected by the word line selection signal X1.

The word line selection signal X1 is used for the selection of the word lines WL0 to WL3 to be activated as described above, and also for the generation of the first control signal CUTD0 and the second control signal #CUTD0. For example, the word line selection signal X1 at H level selects the first control signal CUTD0 and also does not select the second control signal #CUTD0, and at L level, does not select the first control signal CUTD0 and selects the second control signal #CUTD0.

Between the first digit line D0 and the first sense node SAN0, there is the first switch DSW0 which gives permission for the connection of the first digit line D0 to the sense amplifier 10. Between the second digit line #D0 and the second sense node #SAN0, there is the second switch #DSW0 which gives permission for the connection of the second digit line #D0 to the sense amplifier 10. As described above, the control circuit 11 generates the first control signal CUTD0 according to the word line selection signal X1, outputs the first control signal CUTD0 to the first switch DSW0, and also generates the second control signal #CUTD0 according to the word line selection signal X1, and outputs to the second switch #DSW0.

In other words, the control circuit 11 controls the conductive state of the first switch DSW0 using the first control signal CUTD0 in order to switch whether or not to connect the first digit line D0 to the sense amplifier 10. Further, the control circuit 11 controls the conductive state of the second switch #DSW0 using the second control signal #CUTD0 in order to switch whether or not to connect the second digit line #D0 to the sense amplifier 10. A transistor can be used to form the first switch DSW0 and the second switch #DSW0, for example.

As described above, in the semiconductor device according to this exemplary embodiment, the control circuit 11 has the configuration that can separately control the conductive state of the first switch DSW0 and the second switch #DSW0 by generating the first control signal CUTD0 and the second control signal #CUTD0. Then, the first digit line DO and the second digit line #D0 can be individually activated or deactivated.

Further, the semiconductor device includes a first reading switch SW0, which is connected between the first sense node SAN0 and a first reading node GIOD0, a second reading switch #SW0, which is connected between the second sense node #SAN0 and a second reading node #GIOD0, and a reading control circuit 12 which outputs a reading control signal. The reading control signal controls the conductive state of the first reading switch SW0 and the second reading switch #SW0.

In the period while either the first switch DSW0 or the second switch #DSW0 is disconnected, the reading control circuit 12 makes both the first reading switch SW0 and the second reading switch #SW0 conductive, transmits the voltage of the first sense node SAN0 to the first reading node GIOD0, and the voltage of the second sense node #SAN0 to the second reading node #GIOD0.

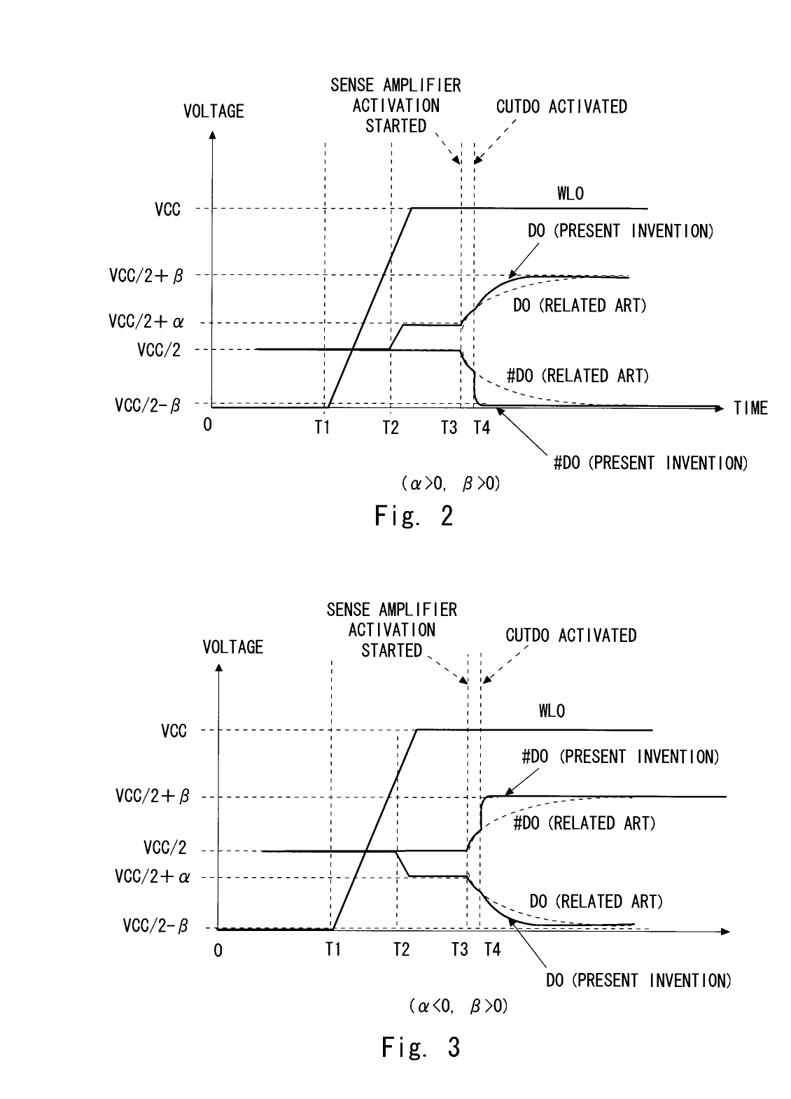

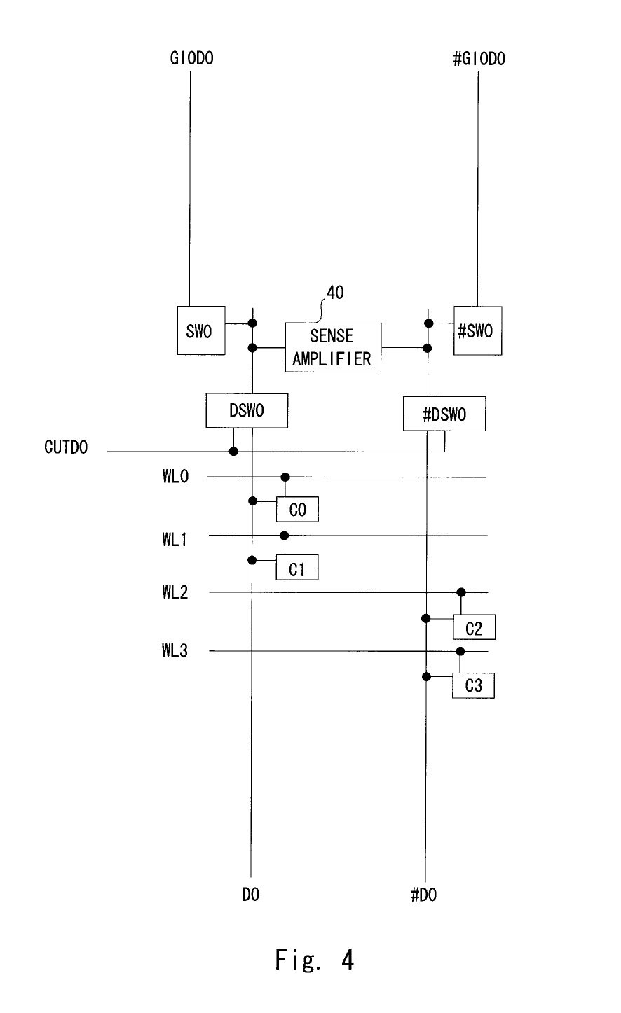

Next, the reading operation of the semiconductor device configured in this way is explained. FIG. 2 illustrates the operation of the semiconductor device according to the exemplary embodiment of the present invention. In FIG. 2, the vertical axis indicates voltage and the horizontal axis indicates time. An example of reading data stored in the memory cell C0 is explained as an example hereinafter. In FIG. 2, the solid lines indicate the voltages of the word line WL0, the digit lines D0 and #D0 of the semiconductor device according to this exemplary embodiment. The dotted lines indicate the voltages of the digit lines D0 and #D0 in the semiconductor device according to the related art illustrated in FIG. 4.

At the time T1, if the voltage of the word line selection control signal X1 for activating the word lines WL0 and WL1 becomes zero, the voltage of the word line WL0 increases. Then, the voltage of the word line WL0 reaches the power supply voltage level, and becomes constant. Further, both of the voltages of the first digit line D0 and the second digit line #D0 become the precharge voltage (VCC/2).

When the word line WL0 is activated at the time T1, the memory cell C0, which is connected to the word line WL0, is connected to the digit line D0. Then, a potential difference according to the value of the data stored in the memory cell C0 is generated (at the time T2) between the first digit line D0 and the second digit line #D0. Note that the memory cell C0 connected to the selected word line WL0 is connected to the first digit line D0, and the memory cell C0 is not connected to the second digit line #D0. Specifically, the voltage of the first digit line D0 to which the memory cell C0 to be read is connected is set to VCC/2+α. On the other hand, the voltage of the second digit line #D0 to which the memory cell C0 to be read is not connected remains at VCC/2. Therefore, the potential difference of the digit line pair is α. The α here is either a positive or negative value according to the stored data. However in FIGS. 2, α and β are assumed to be positive values.

Next, at the time T3, after sufficient potential difference (α) to amplify between the digit line pair is generated, the sense amplifier 10 is activated. Then, the sense amplifier 10 starts to amplify the potential difference between the digit lines. At this time, both of the first switch DSW0 and the second switch #DSW0 are turned on by the first control signal CUTD0 and the second control signal #CUTD0. The first switch DSW0 and the second switch #DSW0 should be turned on at least at the time when the activation of the sense amplifier 10 is started. The first switch DSW0 and the second switch #DSW0 may be turned on before the time T3 when the activation of the sense amplifier 10 is started.

After that, the control circuit 11 switches the second switch #DSW0 from on to off and disconnects the second digit line #D0, which is a non-reading digit line, from the sense amplifier 10 in response to the increase in the amplified potential difference between digit lines (potential difference between the first and second sense nodes SAN0 and #SAN0) due to the influence such as electrical noise to the extent that the magnitude relationship between the potential difference is not inverted. In this exemplary embodiment, the capability of the sense amplifier 10 is estimated in the design phase, and the length of the period from the time T3 to T4 (for example, predetermined time) is specified. Then, the second switch #DSW0 is switched off from on based on the predetermined time. Specifically, after the predetermined time from the time T3 (which is at the time T4), by switching the control signal #CUTD0, the second switch #DSW0 may be switched off from on.

The timing to disconnect the second digit line #D0 (non-reading digit line) to which the memory cell C0 to be read is not connected from the sense amplifier 10 (the time 4), that is, the timing to switch the second switch #DSW0 from on to off can be determined by the adjustment in the design stage of various products.

Since the time T4, only the first digit line D0 to which the memory cell C0 to be read is connected is amplified by the sense amplifier 10, and the voltage increases by β from VCC/2 after the time T4 to the voltage. On the other hand, the voltage of the second digit line #D0 (non-reading digit line) to which the memory cell C0 to be read is not connected decreases by β from VCC/2. The voltage of the first digit line D0 to which the memory cell C0 to be read is connected increases to VCC/2+β faster than the semiconductor device of the related art. Further, the voltage of the second digit line #D0 to which the memory cell C0 to be read is not connected decreases to VCC/2−β faster than the semiconductor device of the related art.

Next, the case where α is a negative value is explained. Note that β shall be a positive value. FIG. 3 illustrates the operation of the semiconductor device in the case α is a negative value. As illustrated in FIG. 3, if the word line WL0 is activated at the time T1, the potential difference α according to the data stored in the memory cell C0 is generated between the digit lines at the time T2.

At the time T3, after sufficient potential difference (α) to amplify between the digit line pair is generated, the sense amplifier 10 is activated. Then, the sense amplifier 10 starts to amplify the potential difference between the digit lines. At this time, both of the first switch DSW0 and the second switch #DSW0 are turned on by the first control signal CUTD0 and the second control signal #CUTD0.

If the potential difference(potential difference between the first sense node SAN0 and the second sense node #SAN0) between the digit lines increases due to the influence such as electrical noise to the extent that the magnitude relationship between the potential difference is not inverted, the control circuit 11 switches the second switch #DSW0 from on to off. That is, the second digit line #D0 (non-reading digit line) to which the memory cell C0 to be read is not connected is disconnected from the sense amplifier 10. Then, since the time T4, only the first digit line D0 (reading digit line) to which the memory cell C0 to be read is connected is amplified by the sense amplifier 10, and the voltage of the first digit line D0 decreases to VCC/2−β. On the other hand, the voltage of the second digit line #D0 (non-reading digit line) to which the memory cell C0 to be read is not connected increases by β(>0) from VCC/2.

In a similar manner as the related art, by switching the first reading switch SW0 and the second reading switch #SW0, the amplified potential of the first digit line D0, which is explained with reference to FIGS. 2 and 3, is transferred outside the memory array via the digit line selection circuit (not illustrated), and can be read outside the semiconductor device. Note that the digit line selection circuit is connected to the first reading node GIOD0 and the second reading node #GIOD0.

In a similar manner as the reading operation of the memory cell C0, in order to read the data stored in the memory cell C2, which is connected to the second digit line #D0, it is X1=1 and the word line WL2 is activated. Then, the control signals CUTD0 and #CUTD0 are controlled so that the first switch DSW0 is switched off from on at the time T5 of FIG. 3, and the second switch #DSW0 remains to be on. In other words, while the sense amplifier 10 is amplifying the potential difference between the digit line pair, the second digit line #D0 to which the memory cell C2 to be accessed is always connected to the sense amplifier 10. On the other hand, the connection between the first digit line D0, to which the memory cell C2 to be read is not connected, and the sense amplifier 10 is aborted on the way. This enables to read the data in the memory cell C2.

Next, exemplary advantages of the semiconductor device according to this exemplary embodiment configured in this way are explained. In this exemplary embodiment, as mentioned above, after activating the sense amplifier 10, if the data between the digit line pair is amplified to the level in which erroneous amplification is not performed due to some sort of electrical noise, the digit line (non-reading digit line), to which the memory cell to be read is not connected, is disconnected from the sense amplifier 10. Then, the resistance and the capacitance of the digit line pair D0 and #D0, which is to be amplified by the sense amplifier, are effectively and remarkably reduced for the sense amplifier 10. This reduces the load imposed on the sense amplifier 10 during the amplification period, and the time required for amplifying the digit lines is speeded up compared to the semiconductor device of the related art which amplifies the voltages of the two digit lines.

Further, the digit line, to which the memory cell to be read is not connected, is disconnected from the sense amplifier 10 immediately after starting the amplification, thus the voltage is set to the potential stable point VCC/2−β (or VCC/2+β) at once. In the related art, the voltage of the digit line to which the memory cell to be read is not connected is controlled to be VCC/2−β (or VCC/2+β) by the drive capability of the sense amplifier 10. In this exemplary embodiment, as the voltage of the digit line, to which the memory cell to be read is not connected, is immediately set to the potential stable point VCC/2−β (or VCC/2+β), it is possible to improve the drive capability of the sense amplifier 10 for the digit line (reading digit line) to which the memory cell to be read is connected.

Further, the total length of the digit lines to be amplified can be reduced, thereby enabling to also reduce the current consumption during the amplification period.

It is preferable that the semiconductor device according to this exemplary embodiment is used as a memory of a communication device which is required for high-speed reading operations, such as a router. This achieves to miniaturize the communication devices such as a router, and also high-speed reading operation.

The present invention is not limited to the above exemplary embodiment, but may be modified within the scope of the present invention.

For example, in the above explanation, the timing to disconnect the digit lines not connected to the memory cell to be read from the sense amplifier 10 is specified beforehand by estimating the capability of the sense amplifier 10. However the digit lines may be disconnected from the sense amplifier 10 by monitoring the potential difference between the digit line pair and detecting that the potential difference becomes more than or equal to a threshold.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a plurality of memory cells;
a first digit line and a second digit line, one of the first digit line and the second digit line being coupled to the memory cell to be read among the plurality of memory cells;
a sense amplifier including a first sense node and a second sense node that are respectively connected to the first digit line and the second digit line;
a first switch that is interposed between the first digit line and the first sense node;
a second switch that is interposed between the second digit line and the second sense node; and
a control circuit that outputs a first control signal and a second control signal for controlling a conducive state of the first switch and the second switch,
wherein at the time of starting an activation of the sense amplifier, the control circuit makes the first switch and the second switch conductive, and disconnects one of the first switch and the second switch corresponding to the digit line to which the memory cell to be read is not connected according to a potential difference between the first sense node and the second sense node.

2. The semiconductor device according to claim 1, wherein in a period of reading the memory cell to be read, the control circuit maintains the conductive state of the digit line to which the memory cell to be read is connected and one of the first switch and the second switch that corresponds the digit line.

3. The semiconductor device according to claim 1, wherein the control circuit controls the first switch and the second switch according to a word line selection control signal that activates a word line for selecting the memory cell to be read.

4. The semiconductor device according to one of claims 1, wherein the control circuit controls the first switch and the second switch according to time elapsed since the activation of the sense amplifier is started.

5. The semiconductor device according to one of claims 1, further comprising:
a first reading switch that is connected between the first sense node and a first reading node;
a second reading switch that is connected between the second sense node and a second reading node; and
a control circuit that outputs a reading control signal for controlling a conductive state of the first reading switch and the second reading switch,
wherein the reading control circuit makes the first reading switch and the second reading switch conductive in a period while one of the first switch and the second switch is disconnected.

6. The semiconductor device according to one of claims 1, wherein the memory cell is a memory cell in a DRAM.

7. A method of reading data in a semiconductor device including a plurality of memory cells, a first digit line and a second digit line, one of the first digit line and the second digit line being coupled to the memory cell to be read among the plurality of memory cells, and a sense amplifier that includes a first sense node and a second sense node that are respectively connected to the first digit line and the second digit line, the method comprising:
at the time of starting an activation of the sense amplifier, connecting the first digit line and the second digit line to the first sense node and the second sense node and disconnecting one of the first digit line and the second digit line to which the memory cell to be read is not connected from the sense amplifier according to a potential difference between the first sense node and the second sense node.

8. The method according to claim 7, further comprising maintaining the connection state between the digit line which is connected to the memory cell to be read and one of the first sense node and the second sense node that corresponds to the digit line in a period of performing a reading operation of the memory cell to be read.

9. The method according to claim 7, further comprising controlling the connection between the first digit line and the second digit line to the sense amplifier according to a word line selection control signal that activates a word line to select the memory cell to be read.

10. The method according to one of claims 7, further comprising controlling the connection between the first digit line and the second digit line to the sense amplifier according to time elapsed since the activation of the sense amplifier is started.

11. The method according to one of claims 7, further comprising in a period of disconnecting one of the first digit line and the second digit line from the sense amplifier, transmitting a voltage of the first sense node to a first reading node and transmitting a voltage of the second sense node to a second reading node.

12. The method according to one of claims 7, wherein the memory cell is a memory cell in a DRAM.
